(19) United States
(12) Patent Application Publication
(10) Pub. No.: US 2025/0391759 A1
(43) Pub. Date: Dec. 25, 2025

(54) PACKAGE STRUCTURE AND MANUFACTURING METHOD THEREOF

(71) Applicant: JCET Management Co., Ltd., SHANGHAI CITY (CN)

(72) Inventors: Xiao GU, SHANGHAI CITY (CN); Lihong LIU, SHANGHAI CITY (CN); Jiongjiong GU, SHANGHAI CITY (CN)

(73) Assignee: JCET Management Co., Ltd., SHANGHAI CITY (CN)

(21) Appl. No.: 19/245,418

(22) Filed: Jun. 23, 2025

(30) Foreign Application Priority Data
Jun. 24, 2024 (CN) 202410819029.6

(51) Int. Cl. H01L 23/498; H01L 23/31

(52) U.S. Cl. CPC H01L 23/49838; H01L 23/3135; H01L 23/49811

(57) ABSTRACT

A package structure and a related manufacturing method thereof are disclosed. The package structure includes: a first redistribution structure; a chip and a first conductive pillar that are located on a surface of the first redistribution structure; a second redistribution structure located on a back surface of the chip; a conductive connection layer that is located on the surface of the first conductive pillar and that is connected to the second redistribution structure; and a molding layer that is located on the surface of the first redistribution structure and that encapsulates the chip, the first conductive pillar, the conductive connection layer, and the second redistribution structure. A size and a thickness of the package are reduced, and the number of I/Os of the package is increased; and heat dissipation performance of the package and performance consistency are improved.

### CROSS-REFERENCE TO RELATED APPLICATION

This application claims priority under 35 U.S.C. § 119(a) to Chinese Patent Application No. CN202410819029.6, filed on Jun. 24, 2024. The entire content of the above-identified application is incorporated herein by reference.

### TECHNICAL FIELD

The present disclosure relates to the technical field of packaging, and specifically to a package structure and a manufacturing method thereof.

### BACKGROUND

With the increasing requirements of electronic products for packaging integration, SiP emerges, which greatly reduces sizes of electronic devices. However, as end products tend to be thinner and lighter, it is difficult to further reduce the size of the SiP. For example, FIG. 1, is a schematic diagram of a conventional package structure, which includes a substrate 10 and a chip 20 and a passive component 30 that are located on a surface of the substrate. It can be seen that because the package thickness is limited by a height of a component, a thickness of the substrate thickness cannot be further reduced, and the passive component 30 occupies most of the substrate area, and the space left for the chip is small, and even the number of I/Os is limited. In addition, under the condition that the substrate area is insufficient, chips need to be installed on both sides of the substrate, which results in poor heat dissipation.

### SUMMARY

The present disclosure provides a package structure and a manufacturing method thereof, which aims to solve the problem that it is difficult to further reduce a size of an existing package structure.

To achieve the foregoing objective, the present disclosure provides a package structure, including: a first redistribution structure;
a chip and a first conductive pillar that are located on a surface of the first redistribution structure, where an electrical connection surface of the chip faces the first redistribution structure;
a second redistribution structure located on a back surface of the chip, where the second redistribution structure includes a thin film passive component, and the electrical connection surface of the chip and the back surface of the chip are opposite to each other;
a conductive connection layer that is located on the surface of the first conductive pillar and that is connected to the second redistribution structure;
a molding layer that is located on the surface of the first redistribution structure and that encapsulates the chip, the first conductive pillar, the conductive connection layer, and the second redistribution structure; and
a metal layer located on a surface of the second redistribution structure, where a surface of the metal layer is exposed out of the molding layer.

Preferably, the package structure further includes:
a second conductive pillar located on a surface of the conductive connection layer, where a surface of the second conductive pillar is exposed out of the molding layer.

Preferably, the package structure further includes:
solder bumps located on the surface of the conductive connection layer, where the molding layer encapsulates the solder bumps. Preferably, the molding layer includes a first molding layer and a second molding layer, where
the first molding layer is located on the surface of the first redistribution structure and encapsulates the chip and the first conductive pillar, the back surface of the chip and an upper surface of the first conductive pillar are exposed out of an upper surface of the first molding layer, and the conductive connection layer is also located on the surface of the first molding layer; and
the second molding layer is located on the surface of the first molding layer and encapsulates the second redistribution structure and the conductive connection layer.

Preferably, the second redistribution structure includes a plurality of second redistribution layers; each second redistribution layer includes a second dielectric layer and a second conductive line extending through the second dielectric layer; and there is at least one thin film passive component, and the at least one thin film passive component is located at a corresponding second redistribution layer.

Preferably, the first redistribution structure is a substrate.

Preferably, the second redistribution structure is located in the middle of the back surface of the chip, and the conductive connection layer covers a part of an edge of the back surface of the chip.

Preferably, the conductive connection layer and the second redistribution structure are of an integral structure. Preferably, the package structure further includes:
a solder ball located on a side surface that is of the first redistribution structure and that is away from the chip. Correspondingly, the present disclosure further provides a manufacturing method for a package structure, including:
providing a temporary carrier board;
forming an adhesive layer on a surface of the temporary carrier board;
arranging a chip and a first conductive pillar on a surface of the adhesive layer, where an electrical connection surface of the chip faces the adhesive layer;
forming a first molding layer for packaging the chip and the first conductive pillar on the surface of the adhesive layer, where a back surface of the chip and an upper surface of the first conductive pillar are exposed out of an upper surface of the first molding layer, and the electrical connection surface of the chip and the back surface of the chip are opposite to each other;
forming a second redistribution structure on the back surface of the chip, and forming, on a surface of the first conductive pillar and a surface of the first molding layer, a conductive connection layer for connecting the second redistribution structure and the first conductive pillar, where the second redistribution structure includes a thin film passive component;
forming, on the surface of the first molding layer, a second molding layer for packaging the second redistribution structure and the conductive connection layer;
removing the temporary carrier board and the adhesive layer; and
forming a first redistribution structure on the electrical connection surface of the chip, a lower surface of the first conductive pillar, and a lower surface of the first molding layer.

The step of forming the second redistribution structure further includes:
forming a metal layer on a surface of the second redistribution structure, where a subsequently formed second molding layer exposes a surface of the metal layer.

Preferably, the step of forming the conductive connection layer further includes:
forming a second conductive pillar on a surface of the conductive connection layer, where the subsequently formed second molding layer exposes a surface of the second conductive pillar.

Preferably, the step of forming the conductive connection layer further includes:
forming solder bumps on the surface of the conductive connection layer, where the subsequently formed second molding layer encapsulates the solder bumps.

Preferably, the step of forming the second redistribution structure on the back surface of the chip further includes:
sequentially forming, on the back surface of the chip, a plurality of second redistribution layers and thin film passive components located at the second redistribution layers to obtain the second redistribution structure, where
each second redistribution layer includes a second dielectric layer and a second conductive line extending through the second dielectric layer, includes at least one thin film passive component.

Preferably, the step of forming the second redistribution structure on the back surface of the chip further includes:
forming the conductive connection layer together in the process of forming the second redistribution structure on the back surface of the chip, where the conductive connection layer and the second redistribution structure are of an integral structure.

Preferably, the step of forming the first redistribution structure on the electrical connection surface of the chip, the lower surface of the first conductive pillar, and the lower surface of the first molding layer includes:
sequentially forming a plurality of first redistribution layers on the electrical connection surface of the chip, the lower surface of the first conductive pillar, and the lower surface of the first molding layer to obtain the first redistribution structure.

Preferably, the step after forming of the first redistribution structure further includes: forming a solder ball on a side surface that is of the first redistribution structure and that is away from the chip.

The present disclosure has the following beneficial effects:

The present disclosure provides a package structure and a manufacturing method thereof. The package structure includes: a first redistribution structure; a chip and a first conductive pillar that are located on a surface of the first redistribution structure, where an electrical connection surface of the chip faces the first redistribution structure; a second redistribution structure located on a back surface of the chip, where the second redistribution structure includes a thin film passive component, and the electrical connection surface of the chip and the back surface of the chip are opposite to each other; a conductive connection layer that is located on the surface of the first conductive pillar and that is connected to the second redistribution structure; and a molding layer that is located on the surface of the first redistribution structure and that encapsulates the chip, the first conductive pillar, the conductive connection layer, and the second redistribution structure. A size and a thickness of the package are reduced, and the number of I/Os of the package is increased. In addition, conventional passive components are replaced with thin film passive components, so that there is space for more chips on one side surface of the substrate, and heat dissipation performance of the package is better. Further, parasitic parameters of the thin film passive components are small, and performance consistency is better by combining thin film passive components into a complete package structure.

### BRIEF DESCRIPTION OF DRAWINGS

FIG. 1 is a schematic diagram of a conventional package structure;

FIG. 2 is a schematic diagram of a second redistribution structure of a package structure according to some embodiments of the present disclosure;

FIG. 3 to FIG. 6 are schematic diagrams of a package structure according to some embodiments of the present disclosure; and

FIG. 7 to FIG. 14 are schematic diagrams of a manufacturing process of a package structure according to some embodiments of the present disclosure.

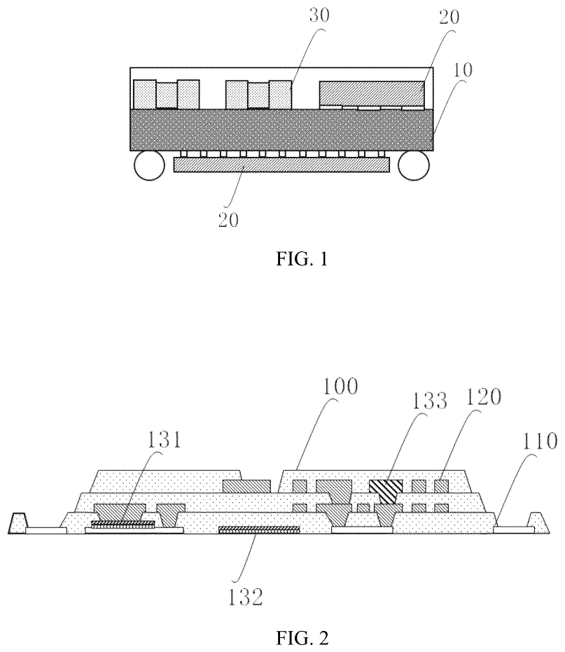

### DETAILED DESCRIPTION OF EMBODIMENTS

The following clearly and completely describes the technical solutions in the embodiments of the present disclosure with reference to the accompanying drawings in the embodiments of the present disclosure. Apparently, the described embodiments are merely some but not all of the embodiments of the present disclosure. All other embodiments obtained by a person of ordinary skill in the art based on the embodiments of the present disclosure without creative efforts shall fall within the protection scope of the present disclosure.

As used herein, terms such as “first”, “second”, and “third” describe various components, assemblies, regions, layers, and/or segments, which shall not be limited by such terms. These terms can be used simply to distinguish one component, assembly, region, layer, or segment from another. For example, the terms “first”, “second”, and “third” are used herein without implying an order or a sequence, unless clearly indicated by the context.

For ease of description, spatially relative terms such as “under”, “below”, “lower”, “above”, “over”, “upper” and the like may be used herein to describe a relationship of one component or feature to other components or features as illustrated in the accompanying drawings. It should be understood that the spatially relative terms are intended to encompass different orientations of the device in use or operation in addition to the orientation depicted in the accompanying drawings. For example, if the device in the accompanying drawings is turned over, components described as “below” or “under” other components or features would then be oriented “above” the other components or features. Therefore, the term “below” may include “above” and “below” orientations.

In this application, unless otherwise expressly specified and defined, terms such as “connect” and “connected to” should be understood in a broad sense. For example, unless otherwise expressly defined, a “connection” may be a fixed connection, may be a detachable connection, or may be an integrated connection; or may be a mechanical connection or an electrical connection; or may be a direct connection, or an indirect connection through an intermediate medium; or may be an inner connection between two components, or interaction between two components. A person of ordinary skill in the art may understand specific meanings of the foregoing terms in this application according to specific cases.

It should be noted that the terms “including”, “having”, or any other variant thereof in this application are intended to cover a non-exclusive inclusion.

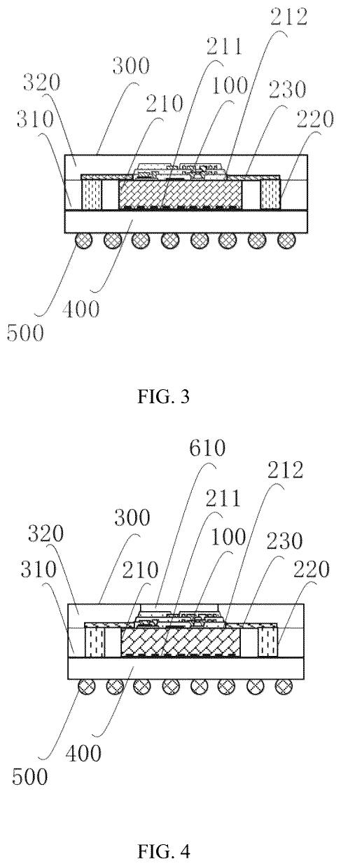

Referring to FIG. 3, some embodiments of the present disclosure provide a package structure, including:
a first redistribution structure 400;
a chip 210 and a first conductive pillar 220 that are located on a surface of the first redistribution structure 400, where an electrical connection surface 211 of the chip faces the first redistribution structure 400;
a second redistribution structure 100 located on a back surface 212 of the chip 210, where the second redistribution structure 100 includes a thin film passive component, and the electrical connection surface 211 of the chip and the back surface 212 of the chip are opposite to each other;
a conductive connection layer 230 that is located on the surface of the first conductive pillar 220 and that is connected to the second redistribution structure 100; and
a molding layer 300 that is located on the surface of the first redistribution structure 400 and that encapsulates the chip 210, the first conductive pillar 220, the conductive connection layer 230, and the second redistribution structure 100.

In some embodiments, the first redistribution structure 400 includes a plurality of first redistribution layers, where the first redistribution layer includes a first dielectric layer and a first conductive line extending through the first dielectric layer. In some embodiments, the first redistribution structure 400 is a substrate. In some embodiments, the substrate may be a resin substrate, a ceramic substrate, a glass substrate, a silicon substrate, or a printed circuit board (PCB).

In some embodiments, the chip 210 may be a logic chip and a memory chip. In some embodiments, the logic chip may include a gate array, a cell substrate array, an embedded array, a structured application specific integrated circuit (ASIC), a field programmable gate array (FPGA), a complex programmable logic device (CPLD), a central processing unit (CPU), a micro processing unit (MPU), a micro controller unit (MCU), a logic integrated circuit (IC), an application processor (AP), a display driver IC (DDI), a radio frequency (RF) chip, or a complementary metal-oxide-semiconductor (CMOS) image sensor. In some embodiments, the memory chip may include a volatile memory chip (such as a dynamic random access memory (DRAM) or a static RAM (SRAM)) or a non-volatile memory chip (such as a flash memory (Flash), a phase change RAM (PRAM), a magnetoresistive RAM (MRAM), a ferroelectric RAM (FERAM) or a resistive CMOS (RERAM)).

In some embodiments, a material of the first conductive pillar 220 may be one or more of aluminum, nickel, tin, tungsten, platinum, copper, titanium, chromium, tantalum, gold, or silver. In some embodiments, the electrical connection surface 211 of the chip is a side surface that has a circuit structure and that is used for electrically connecting to the first redistribution structure 400.

In some embodiments, referring to FIG. 2, the second redistribution structure 100 includes a plurality of second redistribution layers, where each second redistribution layer includes a second dielectric layer 110 and a second conductive line 120 extending through the second dielectric layer 110. In some embodiments, there is at least one thin film passive component, and the at least one thin film passive component is located at a corresponding second redistribution layer. In some embodiments, the thin film passive component may be a capacitor 131, a resistor 132, an inductor 133, or the like. It should be noted that the technology of integrating a thin film passive component into a redistribution structure is a conventional technology, which is not described in detail in this embodiment.

In some embodiments, the second redistribution structure 100 is electrically connected to the first redistribution structure 400 through the conductive connection layer 230 and the first conductive pillar 220. In some embodiments, a material of the conductive connection layer 230 may be one or more of aluminum, nickel, tin, tungsten, platinum, copper, titanium, chromium, tantalum, gold, or silver. In some embodiments, the conductive connection layer 230 is of a plate-like structure.

In some embodiments, a material of the molding layer 300 may be epoxy resin, polyimide resin, benzocyclobutene resin, or polybenzoxazole resin, and the forming process may be an injection molding process or a transfer molding process.

In some embodiments, the molding layer 300 includes a first molding layer 310 and a second molding layer 320; the first molding layer 310 is located on the surface of the first redistribution structure 400 and encapsulates the chip 210 and the first conductive pillar 220, the back surface 212 of the chip and an upper surface of the first conductive pillar 220 is exposed out of an upper surface of the first molding layer 300, and the conductive connection layer 230 is also located on the surface of the first molding layer 310; and the second molding layer 320 is located on the surface of the first molding layer 320 and encapsulates the second redistribution structure 100 and the conductive connection layer 230. In some embodiments, materials of the first molding layer 310 and the second molding layer 320 may be the same or different. In some embodiments, the second redistribution structure 100 is located in the middle of the back surface 212 of the chip, and the conductive connection layer 230 covers a part of an edge of the back surface 212 of the chip.

In some embodiments, the conductive connection layer 230 and the second redistribution structure 100 are of an integral structure.

Referring to FIG. 4, the package structure according to some embodiments of the present disclosure includes: a metal layer 610 located on a surface of the second redistribution structure 100, where a surface of the metal layer 610 is exposed out of the molding layer 300. In some embodiments, a material of the metal layer 610 may be one or more of aluminum, nickel, tin, tungsten, platinum, copper, titanium, chromium, tantalum, gold, or silver. The metal layer 610 may be used to provide heat dissipation for the second redistribution structure 100, the thin film passive component, and the chip 210.

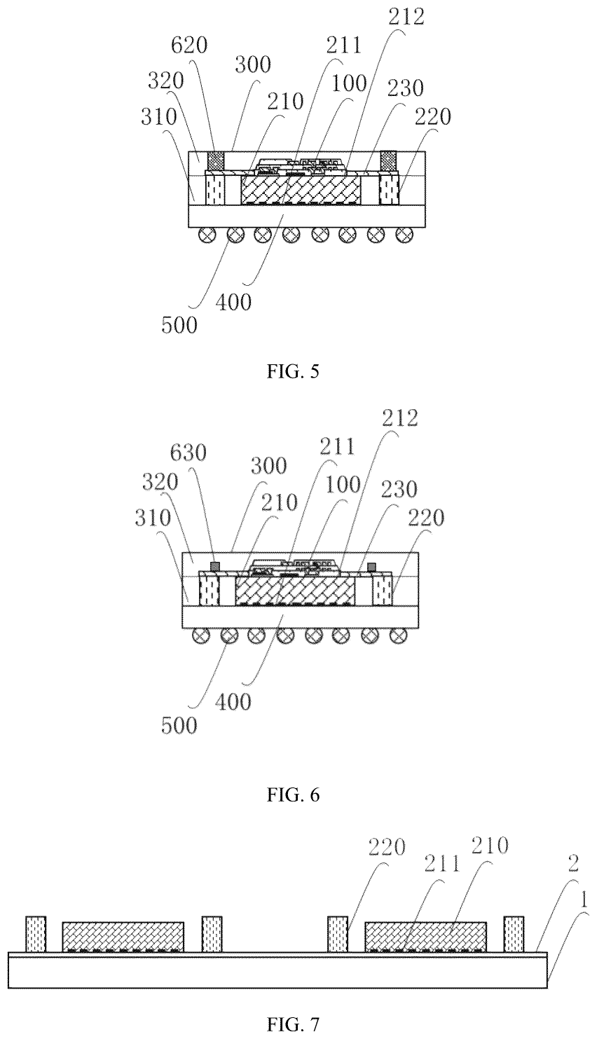

Referring to FIG. 5, the package structure according to some embodiments of the present disclosure includes: a second conductive pillar 620 located on a surface of the conductive connection layer 230, where a surface of the second conductive pillar 620 is exposed out of the molding layer 300. In some embodiments, a material of the second conductive pillar 620 may be metal, and may specifically be one or more of aluminum, nickel, tin, tungsten, platinum, copper, titanium, chromium, tantalum, gold, or silver. The surface of the second conductive pillar 620 may be used for stacking other conductive structures.

Referring to FIG. 6, the package structure according to some embodiments of the present disclosure includes: a plurality of solder bumps 630 located on the surface of the conductive connection layer 230, where the molding layer 300 encapsulates the solder bumps 630. In some embodiments, a material of the solder bump 630 may be one or more of aluminum, nickel, tin, tungsten, platinum, copper, titanium, chromium, tantalum, gold, or silver. In some embodiments, positions and sizes of the plurality of solder bumps 630 may be different; and solder bumps 630 of different sizes are arranged on the surface of the corresponding conductive connection layer 230 to solve the problem of uneven distribution of thin film passive components in the second redistribution structure 100 and the problem of stress imbalance in the package structure that is caused by a large density difference between the second redistribution structure 100 and the conductive connection layer 230, so that stress balance is formed in the package structure, and the package structure is prevented from warping due to stress imbalance.

In some embodiments, referring to FIG. 3, the package structure according to some embodiments of the present disclosure includes: a solder ball 500 located on a side surface that is of the first redistribution structure 400 and that is away from the chip 210. In some embodiments, a material of the solder ball 500 may be one or more of tin, tin-silver, tin-lead, tin-silver-copper, tin-silver-zinc, tin-zinc, tin-bismuth-indium, tin-indium, tin-gold, tin-copper, tin-zinc-indium, or tin-silver-antimony.

Correspondingly, some embodiments of the present disclosure further provide a manufacturing method for a package structure, including:

Referring to FIG. 7, a temporary carrier board 1 is provided; an adhesive layer 2 is formed on a surface of the temporary carrier board 1; and a chip 210 and a first conductive pillar 220 are arranged on a surface of the adhesive layer 2, where an electrical connection surface 211 of the chip faces the adhesive layer 2. In some embodiments, a material of the first conductive pillar 220 may be one or more of aluminum, nickel, tin, tungsten, platinum, copper, titanium, chromium, tantalum, gold, or silver. In some embodiments, the electrical connection surface 211 of the chip is a side surface that has a circuit structure and that is used for electrically connecting to the first redistribution structure 400.

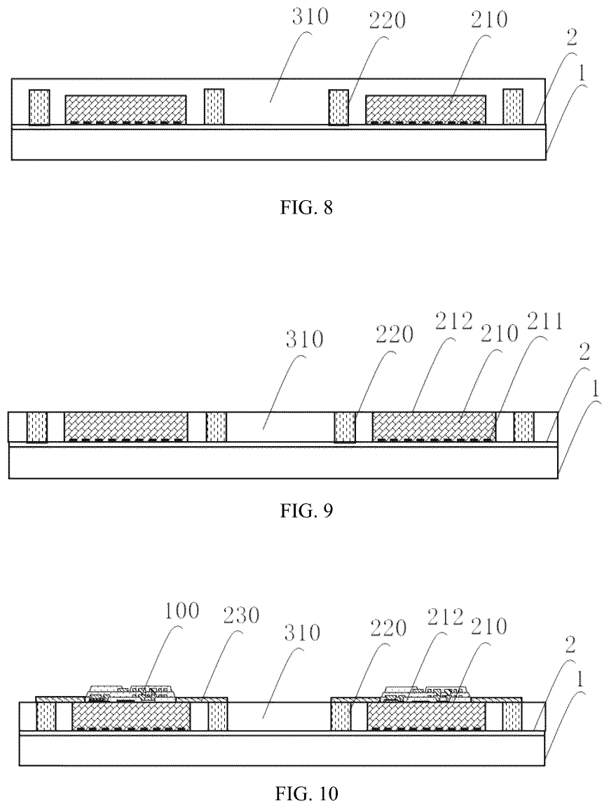

Referring to FIG. 8, a first molding layer 310 for packaging the chip 210 and the first conductive pillar 220 is formed on the surface of the adhesive layer 2; and referring to FIG. 9, a surface of the first molding layer 310 and a surface of the first conductive pillar 220 are ground, so that a back surface of the chip 212 and an upper surface of the first conductive pillar 220 are exposed out of an upper surface of the first molding layer 310, where an electrical connection surface 211 of the chip and the back surface 212 of the chip are opposite to each other. In some embodiments, a material of the first molding layer 310 may be epoxy resin, polyimide resin, benzocyclobutene resin, or polybenzoxazole resin, and the forming process may be an injection molding process or a transfer molding process.

Referring to FIG. 10, a second redistribution structure 100 is formed on the back surface 212 of the chip, and a conductive connection layer 230 for connecting the second redistribution structure 100 and the first conductive pillar 220 is formed on a surface of the first conductive pillar 220 and a surface of the first molding layer 310, where the second redistribution structure 100 includes a thin film passive component. In some embodiments, referring to FIG. 2, the step of forming the second redistribution structure 100 on the back surface 212 of the chip includes: sequentially forming, on the back surface 212 of the chip, a plurality of second redistribution layers and thin film passive components located at the second redistribution layers to obtain the second redistribution structure 100. In some embodiments, referring to FIG. 2, each second redistribution layer includes a second dielectric layer 110 and a second conductive line 120 extending through the second dielectric layer 110. In some embodiments, there is at least one thin film passive component, and the at least one thin film passive component is located at a corresponding second redistribution layer. In some embodiments, the thin film passive component may be a capacitor 131, a resistor 132, an inductor 133, or the like. It should be noted that the technology of integrating a thin film passive component into a redistribution structure is a conventional technology, which is not described in detail in this embodiment. In some embodiments, the second redistribution structure 100 is located in the middle of the back surface of the chip, and the conductive connection layer 230 is also located on the back surface 212 of the chip. In some embodiments, a material of the conductive connection layer 230 may be one or more of aluminum, nickel, tin, tungsten, platinum, copper, titanium, chromium, tantalum, gold, or silver. In some embodiments, the conductive connection layer 230 is of a plate-like structure.

In some embodiments, the step of forming the second redistribution structure 100 on the back surface 212 of the chip further includes: forming the conductive connection layer 230 together in the process of forming the second redistribution structure 100 on the back surface 212 of the chip, where the conductive connection layer 230 and the second redistribution structure 100 are of an integral structure.

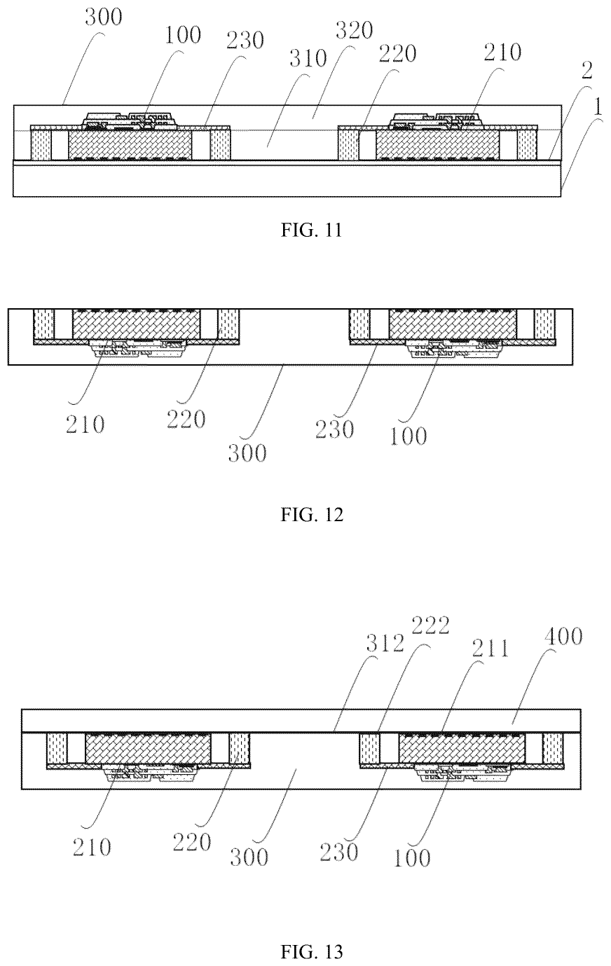

Referring to FIG. 11, a second molding layer 320 for packaging the second redistribution structure 100 and the conductive connection layer 230 is formed on the surface of the first molding layer 310; and in some embodiments, a material of the second molding layer 320 may be epoxy resin, polyimide resin, benzocyclobutene resin, or polybenzoxazole resin, and the forming process may be an injection molding process or a transfer molding process.

In some embodiments, the step of forming the second redistribution structure 100 further includes: forming a metal layer 610 shown in FIG. 4 on a surface of the second redistribution structure 100, where a subsequently formed second molding layer 320 exposes a surface of the metal layer 610. In some embodiments, a material of the metal layer 610 may be one or more of aluminum, nickel, tin, tungsten, platinum, copper, titanium, chromium, tantalum, gold, or silver. The metal layer 610 may be used to provide heat dissipation for the second redistribution structure 100, the thin film passive component, and the chip. It should be noted that the metal layer 610 in this embodiment is formed in the same process as the second redistribution structure 100. In some embodiments, the metal layer 610 may be formed after the step of forming the second redistribution structure 100.

In some embodiments, the step of forming the conductive connection layer 230 further includes: forming a second conductive pillar 620 shown in FIG. 5 on a surface of the conductive connection layer 230, where the subsequently formed second molding layer 320 exposes a surface of the second conductive pillar 620. In some embodiments, a material of the second conductive pillar 620 may be metal, and may specifically be one or more of aluminum, nickel, tin, tungsten, platinum, copper, titanium, chromium, tantalum, gold, or silver. The surface of the second conductive pillar 620 may be used for stacking other conductive structures. It should be noted that the second conductive pillar 620 in this embodiment is formed in the same process as the conductive connection layer 230. In other embodiments, the second conductive pillar 620 may be formed after the step of forming the conductive connection layer 230.

In some embodiments, the step of forming the conductive connection layer 230 further includes: forming solder bumps 630 shown in FIG. 6 on the surface of the conductive connection layer 230, where the subsequently formed second molding layer 320 encapsulates the solder bumps 630. In some embodiments, a material of the solder bump 630 may be one or more of aluminum, nickel, tin, tungsten, platinum, copper, titanium, chromium, tantalum, gold, or silver. In some embodiments, positions and sizes of the plurality of solder bumps 630 may be different; and solder bumps 630 of different sizes are arranged on the surface of the corresponding conductive connection layer 230 to solve the problem of uneven distribution of thin film passive components in the second redistribution structure 100 and the problem of stress imbalance in the package structure that is caused by a large metal line density difference between the second redistribution structure 100 and the conductive connection layer 230, so that stress balance is formed in the package structure, and the package structure is prevented from warping due to stress imbalance. It should be noted that the solder bump 630 in this embodiment is formed in the same process as the conductive connection layer 230. In other embodiments, the solder bump 630 may be formed after the step of forming the conductive connection layer 230.

Referring to FIG. 12, the temporary carrier board 1 and the adhesive layer 2 are removed.

Referring to FIG. 13, a first redistribution structure 400 is formed on the electrical connection surface 211 of the chip, a lower surface 222 of the first conductive pillar, and a lower surface 312 of the first molding layer. In some embodiments, the second redistribution structure 100 is electrically connected to the first redistribution structure 400 through the conductive connection layer 230 and the first conductive pillar 220. In some embodiments, the step of forming the first redistribution structure 400 on the electrical connection surface 212 of the chip, the lower surface 222 of the first conductive pillar, and the lower surface 312 of the first molding layer includes: sequentially forming a plurality of first redistribution layers on the electrical connection surface 211 of the chip, the lower surface 222 of the first conductive pillar, and the lower surface 312 of the first molding layer to obtain the first redistribution structure 400. In some embodiments, the first redistribution structure 400 is a substrate. In some embodiments, the substrate may be a resin substrate, a ceramic substrate, a glass substrate, a silicon substrate, or a printed circuit board (PCB).

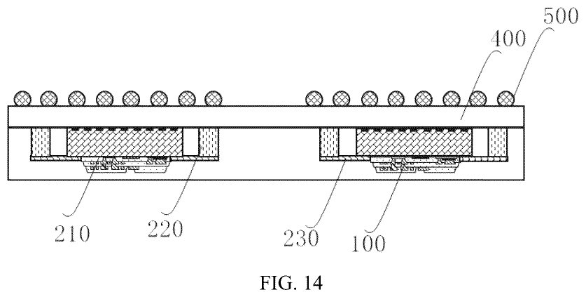

Referring to FIG. 14, the step after forming of the first redistribution structure 400 further includes: forming a solder ball 500 on a side surface that is of the first redistribution structure 400 and that is away from the chip 210. In some embodiments, a material of the solder ball 500 may be one or more of tin, tin-silver, tin-lead, tin-silver-copper, tin-silver-zinc, tin-zinc, tin-bismuth-indium, tin-indium, tin-gold, tin-copper, tin-zinc-indium, or tin-silver-antimony.

The present disclosure has been described with reference to the preferred embodiments, which are not used to limit the present disclosure. Those skilled in the art can make possible variations and modifications to the present disclosure using the disclosed methods and technical contents without departing from the spirit and scope of the present disclosure; and therefore, any simple modifications, equivalent changes and modifications made to the foregoing embodiments according to the technical spirit of the present disclosure without departing from the content of the technical solutions of the present disclosure shall fall within the protection scope of the technical solutions of the present disclosure.

What is claimed is:

1. A package structure, comprising:
a first redistribution structure;
a chip and a first conductive pillar that are located on a surface of the first redistribution structure, wherein an electrical connection surface of the chip faces the first redistribution structure;
a second redistribution structure located on a back surface of the chip, wherein the second redistribution structure comprises a thin film passive component, and the electrical connection surface of the chip and the back surface of the chip are opposite to each other;
a conductive connection layer that is located on the surface of the first conductive pillar and that is connected to the second redistribution structure; and
a molding layer that is located on the surface of the first redistribution structure and that encapsulates the chip, the first conductive pillar, the conductive connection layer, and the second redistribution structure.

2. The package structure according to claim 1, further comprising:
a metal layer located on a surface of the second redistribution structure, wherein a surface of the metal layer is exposed out of the molding layer.

3. The package structure according to claim 1, further comprising:
a second conductive pillar located on a surface of the conductive connection layer, wherein a surface of the second conductive pillar is exposed out of the molding layer.

4. The package structure according to claim 1, further comprising:
solder bumps located on the surface of the conductive connection layer, wherein the molding layer encapsulates the solder bumps.

5. The package structure according to claim 1, wherein the molding layer comprises a first molding layer and a second molding layer;
the first molding layer is located on the surface of the first redistribution structure and encapsulates the chip and the first conductive pillar, the back surface of the chip and an upper surface of the first conductive pillar are exposed out of an upper surface of the first molding layer, and the conductive connection layer is also located on the surface of the first molding layer; and
the second molding layer is located on the surface of the first molding layer and encapsulates the second redistribution structure and the conductive connection layer.

6. The package structure according to claim 1, wherein the second redistribution structure comprises a plurality of second redistribution layers; each second redistribution layer comprises a second dielectric layer and a second conductive line extending through the second dielectric layer; and there is at least one thin film passive component, and the at least one thin film passive component is located at a corresponding second redistribution layer.

7. The package structure according to claim 1, wherein the first redistribution structure is a substrate.

8. The package structure according to claim 1, wherein the second redistribution structure is located in the middle of the back surface of the chip, and the conductive connection layer covers a part of an edge of the back surface of the chip.

9. The package structure according to claim 1, wherein the conductive connection layer and the second redistribution structure are of an integral structure.

10. The package structure according to claim 1, further comprising:
a solder ball located on a side surface that is of the first redistribution structure and that is away from the chip.

11. A manufacturing method for a package structure, comprising:
providing a temporary carrier board;
forming an adhesive layer on a surface of the temporary carrier board;
arranging a chip and a first conductive pillar on a surface of the adhesive layer, wherein an electrical connection surface of the chip faces the adhesive layer;
forming a first molding layer for packaging the chip and the first conductive pillar on the surface of the adhesive layer, wherein a back surface of the chip and an upper surface of the first conductive pillar are exposed out of an upper surface of the first molding layer, and the electrical connection surface of the chip and the back surface of the chip are opposite to each other;
forming a second redistribution structure on the back surface of the chip, and forming, on a surface of the first conductive pillar and a surface of the first molding layer, a conductive connection layer for connecting the second redistribution structure and the first conductive pillar, wherein the second redistribution structure comprises a thin film passive component;
forming, on the surface of the first molding layer, a second molding layer for packaging the second redistribution structure and the conductive connection layer;
removing the temporary carrier board and the adhesive layer; and
forming a first redistribution structure on the electrical connection surface of the chip, a lower surface of the first conductive pillar, and a lower surface of the first molding layer.

12. The manufacturing method for a package structure according to claim 11, wherein the step of forming the second redistribution structure further comprises:
forming a metal layer on a surface of the second redistribution structure, wherein a subsequently formed second molding layer exposes a surface of the metal layer.

13. The manufacturing method for a package structure according to claim 11, wherein the step of forming the conductive connection layer further comprises:
forming a second conductive pillar on a surface of the conductive connection layer, wherein the subsequently formed second molding layer exposes a surface of the second conductive pillar.

14. The manufacturing method for a package structure according to claim 11, wherein the step of forming the conductive connection layer further comprises:
forming solder bumps on the surface of the conductive connection layer, wherein the subsequently formed second molding layer encapsulates the solder bumps.

15. The manufacturing method for a package structure according to claim 11, the step of forming the second redistribution structure on the back surface of the chip further comprises:
sequentially forming, on the back surface of the chip, a plurality of second redistribution layers and thin film passive components located at the second redistribution layers to obtain the second redistribution structure, wherein
each second redistribution layer comprises a second dielectric layer and a second conductive line extending through the second dielectric layer, and there is at least one thin film passive component.

16. The manufacturing method for a package structure according to claim 15, the step of forming the second redistribution structure on the back surface of the chip further comprises: forming the conductive connection layer together in the process of forming the second redistribution structure on the back surface of the chip, wherein the conductive connection layer and the second redistribution structure are of an integral structure.

17. The manufacturing method for a package structure according to claim 11, wherein the step of forming the first redistribution structure on the electrical connection surface of the chip, the lower surface of the first conductive pillar, and the lower surface of the first molding layer comprises:
sequentially forming a plurality of first redistribution layers on the electrical connection surface of the chip, the lower surface of the first conductive pillar, and the lower surface of the first molding layer to obtain the first redistribution structure.

18. The manufacturing method for a package structure according to claim 11, the step after forming of the first redistribution structure further comprises:
forming a solder ball on a side surface that is of the first redistribution structure and that is away from the chip.
